(19) United States
(12) Patent Application Publication
(10) Pub. No.: US 2021/0040620 A1
(43) Pub. Date: Feb. 11, 2021

(54) PROCESS FOR METALLIZING HOLES OF AN ELECTRONIC MODULE BY LIQUID-PHASE DEPOSITION

(71) Applicant: 3D PLUS, Buc (FR)

(72) Inventor: Christian VAL, Saint-Remy-Les-Chevreuse (FR)

(21) Appl. No.: 16/966,805

(22) PCT Filed: Feb. 13, 2019
(86) PCT No.: PCT/EP2019/053548

§ 371 Date: Jul. 31, 2020

(30) Foreign Application Priority Data
Feb. 14, 2018 (FR) 1851215

(51) Int. Cl. C23C 18/16; C23C 18/34; C23C 18/40; H05K 3/42

(52) U.S. Cl. CPC C23C 18/1616; C23C 18/1682; H05K 3/422; C23C 18/40; C23C 18/34

(57) ABSTRACT

A liquid-phase process is provided for depositing metal layers in holes of an electronic module placed in a hermetic chamber, from a chemical liquid containing metal compounds intended to form a metal layer. The holes have a depth P and a diameter D such that D>80 μm and P/D>10, and the process comprises at least one cycle comprising the following substeps: M1) bringing the chamber to a preset pressure P0 and filling the chamber with the liquid; M2) degassing the holes by bringing the chamber to a low pressure P1, with P1<P0; M3) returning the chamber to the pressure P0 and filling the chamber with the liquid; M4) depositing, in the holes, a metal layer issued from the liquid; M5) emptying the liquid from the chamber; and M6) explosively evaporating the liquid remaining in the holes by bringing the chamber to a low pressure P2, with P2<P1<P0; and reiterating the cycle comprising substeps M1 to M6 at least once in order to obtain one new metal layer per iteration.

The field of the invention is that of electronic circuits, whether it be a question of printed circuit boards (or PCBs) or 3D electronic modules, i.e. modules comprising a plurality of stacked levels of components. Certain (PCB or 3D) electronic modules are provided with holes that are drilled vertically, i.e. through the thickness of the module. Specifically, a printed circuit board or a 3D module comprises a plurality of horizontal levels comprising components and electrical conductors; the metallized holes, which are often referred to as vias, pass between these levels and thus allow these conductors to be connected together vertically by contact between the metallized holes and the segments of these conductors that lie flush with the holes. Below, the term “hole” is understood to mean a blind hole or a through-hole. Of course, an electronic module may comprise blind holes and through-holes.

Right from the start, electroless deposition technology is used to metallize these holes and obtain a metal layer, an electrochemical recharging step sometimes being required to complete the metal layer—then referred to as an adhesion layer. Progress in electroless deposition means that it is possible to deposit a layer of several microns without requiring electrodeposition.

It is known to metallize holes by liquid-phase deposition, the printed circuit board or the 3D electronic module being submerged in a liquid containing metal compounds that release metal atoms that deposit on the walls of the holes to form the desired metal layer.

The difficulty of metallization of the walls of holes by liquid-phase deposition increases as the (horizontal) diameter of the holes decreases with respect to their (vertical) depth. The diameter of the holes has a direct effect on the effectiveness of the deposition; more particularly holes of small diameters, i.e. of 80 μm or more, are considered here. PCBs or 3D modules may have thicknesses of 1 to several millimetres. Aspect ratios R between the depth of the hole and its diameter higher than 10 may therefore be achieved.

The higher the aspect ratio R between the depth of the hole and its diameter, the more difficult it is to metallize its walls with a regular thickness and composition. An aspect ratio R of 10 for a hole the diameter of which is 100 μm is considered to be beyond the realms of possibility.

The aim of the invention is to mitigate these drawbacks. Therefore, there remains to this day a need for a process that satisfactorily meets all of the aforementioned requirements, in terms of metallization of holes of aspect ratio R>10 and in particular of small diameters, of an electronic module, simultaneously.

The process according to the invention is based on deposition of a plurality of layers.

More precisely, one subject of the invention is a liquid-phase process for depositing metal layers in holes of an electronic module placed in a hermetic chamber, from a chemical liquid containing metal compounds intended to form a metal layer. It is mainly characterized in that the holes have a depth P and a diameter D such that D>80 μm and P/D>10, and in that the process comprises at least one cycle comprising the following substeps:

M1) Bringing the chamber to a preset pressure P0 and filling the chamber with the liquid,

M2) Degassing the holes by bringing the chamber to a low pressure P1, with P1<P0,

M3) Returning the chamber to the pressure P0 and filling the chamber with the liquid,

M4) Depositing, in the holes, a metal layer issued from the liquid,

M5) Emptying the liquid from the chamber,

M6) Explosively evaporating the liquid remaining in the holes by bringing the chamber to a low pressure P2, with P2<P1<P0,

and in that the cycle comprising substeps M1 to M6 is reiterated at least once in order to obtain one new metal layer per iteration.

Preferably, prior to the first cycle, it comprises a substep of drying the holes by bringing the chamber to a low pressure Pmin, with Pmin<P2.

Prior to this deposition cycle and to this drying substep, the process optionally comprises a plurality of prior steps, called pre-deposition preparing steps, namely, in order:
a step of cleaning the holes, carried out with a cleaning liquid,
a step of etching of conductor segments intercepted by the holes, with an etchant liquid,
a step of pre-dipping in a pre-dip liquid that improves wetting,
a step of activating the walls of the holes with a sensitizing liquid,
a step in a reducing bath with a basic liquid.

Each prior step advantageously comprises the following substeps carried out with a specific liquid of said prior step:

drying the holes by bringing the chamber to a low pressure Pmin, with Pmin<P2,

filling the chamber with the specific liquid of the prior step at a pressure P0,

degassing the holes by bringing the chamber to a low pressure P1, with P1<P0,

filling the chamber with the specific liquid of the prior step, at a pressure P0,

letting the specific liquid of the prior step act for a set length of time,

emptying the chamber,

explosively evaporating the liquid remaining in the holes by bringing the chamber to a low pressure P2, with P2<P1<P0.

The process advantageously comprises, between each prior step, a substep of rinsing the chamber.

P0 is for example equal to atmospheric pressure.

Another subject of the invention is a device for implementing the process such as described, characterized in that it comprises:

a hermetic chamber configured to receive at least one electronic module,

a pressure-regulated vacuum cavity that is connected to a vacuum pump and that is connected to the chamber by a liquid trap,

a reservoir of the liquid, controlled by a liquid pump and connected to the chamber by a pipe for filling the chamber and a pipe for emptying the chamber.

Other features and advantages of the invention will become apparent on reading the following detailed description, which is given by way of nonlimiting example with reference to the appended drawings, in which:

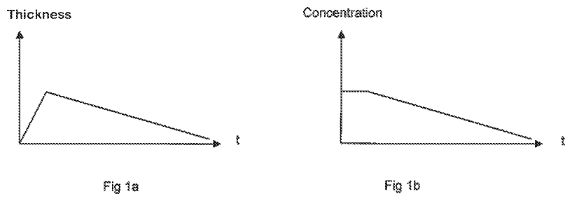

FIGS. 1a and 1b schematically show, as a function of time, the variation in the thickness of a metal layer (FIG. 1a) and the variation in the concentration of metal compounds in a layer (FIG. 1b),

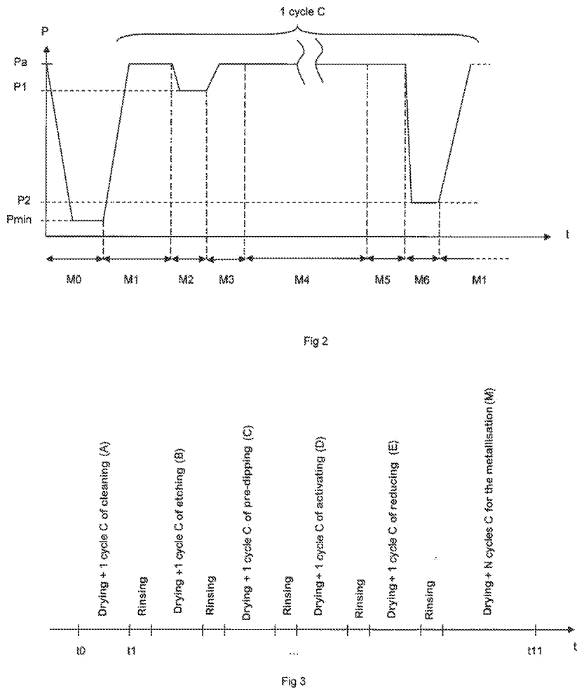

FIG. 2 schematically shows a graph of the pressure of the gases in the chamber as a function of time and the corresponding substeps, for the metallizing step,

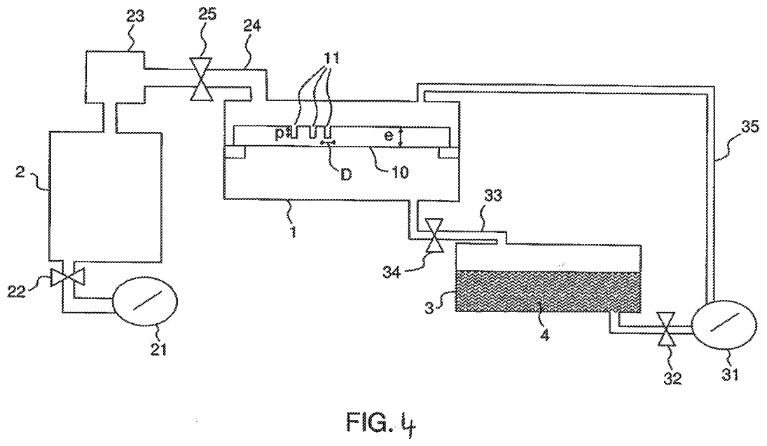

FIG. 3 illustrates the sequence of the steps of the metallizing process with the prior preparing steps,

FIG. 4 schematically shows one example of a device for implementing the process according to the invention, seen in cross section.

In all the figures, elements that are the same have been referenced with the same references.

In the rest of the description, the expressions “horizontal”, and “vertical” are used with reference to the orientation of the described figures. In so far as the device may be positioned with other orientations, the directional terminology is given by way of illustration and is nonlimiting.

For holes of aspect ratio R>10, the liquid filling each hole is not renewed or stirred as in a conventional installation for PCBs having holes of aspect ratio R<10, this leading to a variation in the properties of the metal deposited on the walls of the holes during this metallization phase: the thickness deposited on these walls decreases with time, as does the metal-compound concentration, as illustrated in FIGS. 1a and 1 b. As a result, the concentration of metal compounds in the layer deposited on the walls of the holes (of aspect ratio R>10) is not uniform through its thickness and the thickness of this layer is limited.

The solution according to the invention is based on a renewal of the liquid inside the holes. Thus, a plurality of uniform metal layers will be deposited on top of one another, at the rate of one new layer per renewal of the liquid, in order finally to obtain, on the walls of each hole, a final layer (=sum of the layers deposited on one another) of uniform thickness and uniform concentration.

The metallization process according to the invention will now be described in more detail. The electronic module (PCB or 3D module) 10 provided with holes 11 of depth P (through the thickness e of the module) and of diameter D, is firstly placed horizontally or vertically in a hermetic chamber 1 as may be seen in FIG. 4.

A cycle Cyc of sequential substeps (indicated in FIG. 2) is then carried out:

M1) The chamber is brought to a pressure P0, for example atmospheric pressure (P0=Pa) or a higher pressure; specifically, the fact of being able to increase this pressure above atmospheric pressure has the following advantages: increase in the electrical conductivity of the deposit and of its deposition rate. After the chamber has been brought to the pressure P0, the chamber 1 is filled with a chemical liquid containing metal compounds intended to form the metal layer; the metal compounds are typically copper or nickel or aluminium compounds or compounds of other metals.

M2) Once the chamber 1 has been filled, the holes 11 submerged in the liquid 4 are degassed by decreasing the pressure in the chamber from P0 to P1, the pressure P1 being maintained for a preset length of time in order to achieve this degassing, the pressure difference (P0−P1) being about 50 to 100 mbar. A larger pressure difference would remove too much liquid by evaporation.

M3) The chamber 1 is returned to the pressure P0, and the chamber is filled with the liquid 4.

M4) The liquid is allowed to act on the module and its holes, i.e. in the present case to carry out the operation referred to as liquid-phase chemical deposition (electroless deposition) as is conventional in the metallization of PCBs; this deposition is carried out for a length of time that ensures that the concentration of compounds in the deposited layer remains uniform: the operation is therefore stopped just before the compound concentration of the liquid 4 starts to drop.

M5) The liquid 4 is emptied from the chamber 1.

M6) The liquid 4 trapped in the holes 11 is then “explosively” evaporated: a large negative pressure (P0−P2) possibly reaching several hundred mbars (for example 500 mbars<P2<700 mbars) is applied to the chamber 1 and this pressure P2 is maintained for 2 to 10 seconds, in order to completely vaporize in a very short time the liquid 4 trapped in the holes 11 (explosive evaporation) so as to entrain any non-adherent fines that might have fallen into the bottom of the holes.

At the end of this cycle Cyc of substeps M1 to M6, a metal layer is thus deposited on the walls of the holes 11 of the printed circuit boards or the 3D modules.

This cycle Cyc is reiterated in the same way (same pressures, same renewed liquid, and generally same substep lengths) so as to obtain a new metal layer in each iteration, these layers being uniform. The number N of cycles Cyc is determined by the thickness of the final layer (=sum of the layers) to be achieved and is also related to the metal concentration of the deposition liquid; specifically, below a certain concentration, for example comprised between 25% and 50%, a renewal of the liquid and therefore a new cycle is necessary. N is commonly comprised between 5 and 20. This set of N cycles typically lasts between 1 h and 2.5 h, the substep M4 of course being the longest of the substeps. The expression “step of metallizing the holes” is understood to mean this set of N cycles Cyc.

Preferably, before the first cycle Cyc, a step M0 of drying the holes 11 is carried out by degassing under a high vacuum Pmin of the chamber and maintenance of this pressure Pmin, so as to remove any water present on the walls of the holes. For example, 1 mbar<Pmin<100 mbars.

All these substeps are carried out in a neutral atmosphere, for example in nitrogen or dry air, so as not to oxidize the partial deposits formed in each cycle.

Preferably, prior to the first cycle, i.e. prior to the step of metallizing the holes, various steps are carried out, which aim to prepare for the metallizing step; they are shown in FIG. 3. It is a question of steps of:

A) cleaning the holes 11 with a cleaning liquid 4, in order in particular to remove nonmetals such as for example dielectrics and moulding resin,

B) etching the segments of horizontal electrical conductors intercepted by the holes 11 with an acid etchant liquid 4, in order to improve the adherence of the segments to the future metallization of the holes,

C) pre-dipping the holes 11 in a pre-dip liquid 4, in order to improve the wettability of the walls of the holes 11 with a view to the following step,

D) activating the walls of the holes 11 with a sensitizing catalyst liquid 4 (commercially available liquid), often of palladium type,

E) reducing in a reducing bath with a commercially available basic liquid 4, in order to reduce ions created by the preceding step (palladium ions for example) to atoms and prepare the electroless catalytic reaction of the metal (copper or nickel or aluminium in our example).

No layer is deposited at the end of the steps A) to E).

Each of these steps lasts between 25 and 250 seconds, and comprises the following substeps carried out with the specific liquid of the step:

degassing under a high vacuum Pmin of the chamber 1 so as to remove any water present on the walls of the holes 11,

bringing the chamber to a pressure P0 and filling the chamber 1 with the specific liquid 4 of the step,

once the chamber has been filled, degassing the holes 11 submerged in the liquid 4 by decreasing the pressure in the chamber 1 from P0 to P1, the pressure P1 being maintained for a preset length of time in order to achieve this degassing,

returning the chamber 1 to the pressure P0, and filling the chamber 1 with the specific liquid 4 of the step,

letting the liquid act, i.e. the specific liquid 4 of the step is left in the chamber 1 for the time it takes for the function of the step (cleaning or etching or pre-dipping or activating or reducing) to be performed; the length of this step varies depending on the step,

emptying the liquid 4 from the chamber 1,

“explosively” evaporating the liquid 4 trapped in the holes 11: a large negative pressure (Pa−P2) possibly reaching several hundred mbars is applied to the chamber 1 and this pressure P2 is maintained, in order to completely vaporize in a very short time the liquid 4 trapped in the holes (explosive evaporation).

These substeps include the substeps M1 to M6 of a metallizing cycle Cyc and also the prior drying step M0; these substeps however differ in the liquid used and in the lengths of the substeps, which vary from one step to the next. As already indicated the cleaning liquid differs from the etchant liquid, etc.; likewise, the length of the substep of degassing the holes submerged in the liquid in the activating step is not necessarily identical to the length of the same degassing substep in the reducing step, etc. The liquids used are typically commercially available liquids.

Preferably, as shown in FIG. 3, the process comprises, between each of steps A) to E), a substep of rinsing the chamber 1, for example with deionized water.

All these substeps of steps A to E may be carried out in a neutral atmosphere, for example in nitrogen or dry air.

These substeps and steps (A to E or M) are advantageously automated.

The pressure values are for example (whatever the step, A to E or M),

1 mbar<Pmin<100 mbars,

500 mbars<P2<700 mbars,

900 mbars<P1<950 mbars,

Pa≤P0≤150 bars, Pa being atmospheric pressure, equal to about 1000 mbars.

These steps are advantageously carried out using the same piece of equipment 100, one example of which is described with reference to FIG. 4. It comprises:

A hermetic chamber 1 in which the electronic module 10 (printed circuit board or 3D electronic module) that comprises holes 11 is placed (in the figure, blind holes 11 have been shown); a plurality of printed circuit boards or 3D modules may be placed in the chamber 1.

A pressure-regulated vacuum cavity 2 that is connected to a vacuum pump 21 associated with a valve 22 and that is connected to the chamber 1 by way of a liquid trap 23 and a pipe 24 equipped with a valve 25.

A reservoir 3 of liquid (this liquid 4 varies depending on the step to be carried out as indicated above), controlled by a liquid pump 31 associated with a valve 32, is connected to the chamber by a pipe 33 for emptying the chamber, which pipe is provided with a valve 34, and by a pipe 35 for filling the chamber.

From one step to the next the liquid 4 used is the specific liquid of the step. For the successive cycles of the metallizing step M, the liquid 4, which is the chemical liquid containing metal compounds, is renewed.

Carrying out the steps (A to E and M) in a closed piece of equipment, i.e. without contact with the exterior, has the following industrial advantages: no pollution of the surrounding inside spaces, and therefore no need to pump away and process air in order to remove therefrom harmful gases given off by the chemical deposition baths.

1. A liquid-phase process for depositing metal layers in holes of an electronic module placed in a hermetic chamber, from a chemical liquid containing metal compounds to form a metal layer, wherein the holes have a depth P and a diameter D such that D>80 μm and P/D>10, and in that the process comprises at least one cycle (Cyc) comprising the following substeps:
M1) Bringing the chamber to a preset pressure P0 and filling the chamber with the liquid,
M2) Degassing the holes by bringing the chamber to a low pressure P1, with P1<P0,
M3) Returning the chamber to the pressure P0 and filling the chamber with the liquid,
M4) Depositing, in the holes, a metal layer issued from the liquid,
M5) Emptying the liquid from the chamber,
M6) Explosively evaporating the liquid remaining in the holes by bringing the chamber to a low pressure P2, with P2<P1<P0, and
reiterating the cycle (Cyc) comprising substeps M1 to M6 at least once in order to obtain one new metal layer per iteration.

2. The process for depositing metal layers according to claim 1, wherein, prior to the first cycle (Cyc), it comprises a substep (M0) of drying the holes by bringing the chamber to a low pressure Pm in, with Pmin<P2.

3. The process for depositing metal layers according to claim 1, wherein, prior to the drying substep (M0), the process comprises a plurality of prior preparing steps, in order:
A) cleaning the holes, carried out with a cleaning liquid,
B) etching of conductor segments intercepted by the holes, with an etchant liquid,
C) pre-dipping in a pre-dip liquid,
D) activating the walls of the holes with a catalyzer liquid, and
E) reducing in a reducing bath with a reducer liquid.

4. The process for depositing metal layers according to claim 1, wherein each prior step (A, B, C, D, E) comprises the following substeps carried out with a specific liquid of said prior step:
drying the holes by bringing the chamber to a low pressure Pmin, with Pmin<P2,
filling the chamber with the specific liquid of the prior step at the pressure P0,
degassing the holes by bringing the chamber to a low pressure P1, with P1<P0,
filling the chamber with the specific liquid of the prior step, at the pressure P0,
letting the specific liquid of the prior step act for a set length of time, emptying the chamber, and
explosively evaporating the specific liquid remaining in the holes by bringing the chamber to a low pressure P2, with P2<P1<P0.

5. The process for depositing metal layers claim 1, further comprising, between each prior step (A, B, C, D, E), a substep of rinsing the chamber.

6. The process for depositing metal layers according to claim 1, wherein the pressure P0 is atmospheric pressure.

7. The process for depositing metal layers according to claim 1, wherein the metal compounds are copper or nickel or aluminium compounds.

8. The process for depositing metal layers according to claim 1, wherein some of the holes are blind.

9. A device for implementing the process for depositing metal layers according to claim 1, further comprising:
a hermetic chamber configured to receive at least one electronic module comprising holes,
a pressure-regulated vacuum cavity that is connected to a vacuum pump and that is connected to the chamber by a liquid trap,
a reservoir of the liquid, controlled by a liquid pump and connected to the chamber by a filling pipe and an emptying pipe.
